(19) United States
(12) Patent Application Publication
(10) Pub. No.: US 2012/0043969 A1
(43) Pub. Date: Feb. 23, 2012

(54) Impedance Tomography Apparatus

(76) Inventors: David Simon Holder, London (GB); Ori Gilad, Ya'akov (IL)

(21) Appl. No.: 13/318,943

(22) PCT Filed: May 6, 2010
(86) PCT No.: PCT/GB10/50738

§ 371 Date: Nov. 4, 2011

(30) Foreign Application Priority Data
May 6, 2009 (GB) 0907806.4

(51) Int. Cl. G01R 27/00

(52) U.S. Cl. 324/600

(57) ABSTRACT

An impedance tomography apparatus is disclosed for the measuring of the electrical activity of excitable tissue. The apparatus comprises a plurality of signal transfer devices adapted for transferring an input signal to a body and receiving an output signal from a body. An input signal generator is adapted to generate an electrical input signal and apply it to at least one of the signal transfer devices. A measurement device is arranged to measure the output signal from the body at least one or more of the remaining signal transfer devices, wherein the input signal generator is adapted to generate an input signal of frequency greater than 100 Hz and less that 5 kHz. This allows the depolarisation of nervous or muscle tissue to be imaged.

This invention relates to an impedance tomography apparatus for the measuring of the electrical activity of excitable tissue and, in particular, for measuring electrical activity due to depolarisation of nervous or muscle tissue, such as the electrical neuronal activity that occurs in the human brain. It also relates to an electrical activity of excitable tissue measurement apparatus using electrical impedance tomography and, in particular, it relates to electrical activity of excitable tissue measurement apparatus using electrical impedance tomography for measuring the depolarisation of nervous or muscle tissue. A method of measuring the electrical activity of excitable tissue is also disclosed.

Electrical impedance tomography is a medical imaging technique that uses measurements of the electrical impedance of a body part to construct an image thereof. Typically, electrodes are used to apply an alternating current to the surface of the skin and the resulting potential is measured. Many measurements are made from different points on the skin and an image of impedance within the body is created using known reconstruction techniques. Thus, electrical impedance tomography provides imaging information regarding the internal electrical properties inside a body based on voltage measurements on its boundary.

A series of measurements of the impedance of the subject may be transformed into a tomographic image using similar methods to X-ray computer tomography. The earliest method, employed in the Sheffield Mark 1 system, considers each measurement as similar to the attenuation of an X-Ray beam and thus indicates the impedance of a volume between the input and output electrodes. Unfortunately, unlike X-rays, the current flow is not a neat defined beam, but a diffuse volume which has graded edges. Nevertheless, a volume of maximum sensitivity may be defined. The change in impedance recorded can, for example, be back projected into a computer simulation of the subject. The back projected sets will overlap to produce a blurred reconstructed image, which can then be sharpened by the use of filters. More advanced image reconstruction techniques are now used, such as the “sensitivity matrix” technique, which will be known to those skilled in the art.

Electrical impedance tomography has been successfully employed in producing reproducible and validated images of the large scale changes which occur in the body in conditions such as in the chest during breathing or in the abdomen during gastric emptying.

WO 2004/036379 discloses such a system which uses impedance data to detect abnormalities or inconsistencies within a subject. It monitors the impedance changes associated with the change in the fluid flow rate in a blood vessel or a change in fluid volume.

Electrical impedance tomography techniques also have the potential for use in the clinical neurosciences, where scalp measurements could be used to obtain images of functional changes in the human or animal brain. Potential uses fall into two groups. Firstly, substantial impedance changes of up to 100% are known to occur in conditions such as ischaemic stroke, epileptic seizures or physiological activity, due to cell swelling or changes in blood volume in the brain. These changes occur over seconds or minutes. Electrical impedance tomography systems developed for this purpose have been shown to produce reproducible images in saline filled tanks and in animal studies with electrodes placed directly on the brain, but it has not yet been successful in human clinical studies.

The second potential application for electrical impedance tomography lies in its use for imaging the much smaller changes and more rapid changes which occur over milliseconds during electrical activity in the brain, nervous or muscular systems. The principle of this application is that the impedance of the neuronal membranes is known to fall during the action potential or during the sub-threshold depolarisations which accompany synaptic activity. This activity is indicative of how information is transferred. The measurement of the electrical activity of excitable tissue through the associated impedance change can provide great insight into brain and muscle activity over measuring the changes due to cell swelling and blood volume. However, there is not a prior art device that can measure and image these changes.

WO 95/02360 discloses a system for measuring bioimpedance and treating mental disorders. The system uses pulses of frequencies in the range 5 kHz to 100 kHz to detect blockage of ionic channels. The system is not appropriate for the measuring of the electrical activity of excitable tissue and, in particular, electrical activity due to depolarisation.

WO 2004/093679 discloses a method for monitoring the response of a nervous system of a body to an applied stimulus. The method involves the collection of voltage measurements related to a stimulus that is initiated at a time delayed relative to the stimulus. The differences between the measurements are interpreted as representing changes in the nervous system activity. This device however is unable to effectively measure the electrical activity of excitable tissue, such as depolarisation.

It is known that impedance across neurons changes during depolarization due to the action potential comprising a self-regenerating wave of electrochemical activity that allows nerve cells to carry a signal over a distance. The basis of the idea for electrical impedance tomography of fast neural activity in the brain is that such changes will occur in bulk in neuronal tissue when neurons in it are discharging. The biophysics of the impedance changes and volume conduction in the brain are such that it is unlikely that fields significantly distant from the source will be large if due to action potentials in myelinated white matter. The largest impedance changes will be due, not to action potentials, but to graded neuronal depolarizations which occur due to synaptic activity in the dendrites of grey matter.

Thus, the theory is that current flows through the extracellular space in the brain at rest. At low applied frequencies, almost none flows through the intracellular compartment, because the cell membrane at rest has a high resistance. When ion channels open during depolarization, current then flows into the intracellular compartment as well. The impedance of a sample is dependent on the total number of charged particles available for the current to flow through. When the intracellular compartment opens, the overall impedance will fall. This effect is primarily resistive, because the current is passing through saline ions in the intracellular and extracellular compartments, which act as conductances. Even though the change in membrane resistance is large when ion channels open (about 80×), the net effect on bulk tissue resistance is relatively small at about a 1% decrease locally in the excitable tissue, because the extracellular path for the current flow is a very good conductor at rest. The magnitude of the impedance change is related to the proportion of neurons discharging in brain tissue.

Thus, the impedance changes associated with action potentials are generally very small and very rapid, which makes them extremely difficult to measure. Thus, impedance tomography of brain function presents unique technical difficulties. In particular, there is significant signal noise which makes extraction of signals notoriously difficult. Low electrical signal levels, high levels of extraneous noise, difficulties of measurement because of the distance from the locality of the effect and the resistivity of the skull all reduce measured changes to the level of the noise. The 50 Hz mains electricity interference lies within the recording bandwidth, as does intrinsic electroencephalogram activity associated with the action potentials. It is known to alleviate the noise effects by filtering or averaging, but such attempts have met with limited success.

It has been shown in several studies that such impedance changes are only realistically detectable using very low frequencies, such as at a few hertz, as at higher frequencies the applied current passes into the intracellular space at rest so there is a negligible change when ion channels open. These studies include Boone K G (1995) “The possible use of applied potential tomography for imaging action potentials in the brain”, University of London, PhD thesis (biophysics); Boone K G, Bayford R H and Holder D S (1995) “Modelling and measurement of the resistance changes that occur during the depolarisation of unmyelinated nervous tissue”, Proceedings of the 9th International Conference on Electrical Bio-impedance, Heidelberg, September 1995 (ISBN 3-88452-960-9) 493-494; Liston A D, Bayford R H, Boone K G, and Holder D S (2000), “Estimation of Impedance Changes Inside the Human Head During Neuronal Depolarisation; Implications for Electrical Impedance Imaging of the Brain.”, World Congress on Medical Physics and Biomedical Engineering, Chicago, 2000; and A D Liston (2004), “Models and image reconstruction in Electrical Impedance Tomography of human brain function.”, Middlesex University PhD Thesis.

Biophysical modeling has indicated that the resistance changes are largest when using direct current and then fall off very rapidly if the applied current has a frequency greater than 100 Hz. Below about 100 Hz applied currents remain in the extracellular space under resting conditions because they cannot enter significantly into the intracellular space across the capacitative cell membrane. During the action potential or neuronal depolarization, the membrane resistance diminishes by about eighty times (as shown in The Journal of General Physiology, Vol 22, 649-670, The Rockefeller University Press, “Electric Impedance of the Squid Giant Axon during Activity”, Kenneth S. Cole and Howard J. Curtis) so that the applied current enters the intracellular space as well. As a result, a known system employs a method in which current is applied at about 2 Hz and comprises a square wave as this maximizes the signal.

In a human study during visual evoked potentials with impedance recording at 50 kHz, no changes larger than noise of about 0.001% were observed (Holder D S (1989), “Impedance changes during evoked nervous activity in human subjects: implications for the application of applied potential tomography (APT) to imaging neuronal discharge.”, Clin Phys Physiol Meas, 10, 267-274). Biophysical modelling and experimental testing on animal tissue such as a crab nerve has found that typical impedance changes at these low frequencies of about 2 Hz are maximised, yielding a change of about 1%. Modelling predicts that when measured from the scalp, such changes would be approximately one thousand times smaller i.e. 0.001% change, because the change due to an active small volume of tissue is diluted by the much larger volume of inactive tissue which current applied to the scalp passes through as well. This is termed a “partial volume” effect. It is also due to the diversion of applied current by the skull, which is resistive. Thus, it will be appreciated that the impedance changes that are required to be measured if neuronal activity is to be imaged are extremely small.

Prior methods of measuring the impedance changes have accordingly utilised input signals of approximately 1 Hz and with a square waveform. A very low frequency square wave was used because it approximates most closely to DC, which the biophysical considerations presented above indicate give the largest signal by a significant degree. As the effects of partial volume and the skull act to decrease the signal recorded on the scalp by several orders of magnitude, the low frequency was chosen which gives the largest signal. In principle, a continuous DC applied current would have been ideal, but a 1 or 2 Hz square wave was used for the technical reason that a DC current can cause skin irritation and other electrochemical effects. These effects degrade the electrode-tissue electrochemical properties and so introduce an artefact due to voltage changes produced by this degradation. It is a standard method in the art to employ a bipolar applied current in neurophysiology for these reasons.

U.S. Pat. No. 5,919,142 discloses a method and apparatus in which a first electrical input signal is applied to a body for a first time and a second electrical input signal is applied to the body for a second time. The first and second electrical input signals are of opposite polarity. The difference between the electrical output signal during the first time period and the electrical output signal during the second time period is determined to use in the reconstruction of an image of neuronal activity. A square waveform of approximately 1 Hz forms the first and second input signals and averaging is performed to further enhance the change in impedance due to neuronal activity signals above the noise. Since unwanted noise, such as electroencephalogram noise, mains noise and the evoked potential are independent of the direction of the excitation current, this is largely cancelled out in the difference measurement. However, the required impedance difference due to the response to the applied stimulus follows the polarity of the injected current and is therefore isolated in the difference measurement.

The apparatus and “subtraction method” disclosed in U.S. Pat. No. 5,919,142 gave improved measurement extraction to resolve the small impedance change from the background noise. In particular, a low frequency bipolar square wave input signal of approximately 1 Hz is used to maximise the impedance change due to neuronal activity and data processing is used to reduce the effect of noise.

Unexpectedly, it has been found that the major source of noise was not electronic or thermal, but the spontaneous electrical activity of the brain; the electroencephalogram noise. The bandwidth of the electroencephalogram noise is from about 1-70 Hz, which is in the bandwidth of the recorded impedance changes during evoked activity. Research found that the electroencephalogram signal is uncorrelated to the evoked activity dependent resistance change and so could be minimised by averaging and other signal processing. Nevertheless, even after 10 minutes of averaging, which is the maximum an awake human subject could be expected to tolerate, the measurements resulting from the averaged EEG were still of the same magnitude as the voltage change due to the evoked activity resistance change.

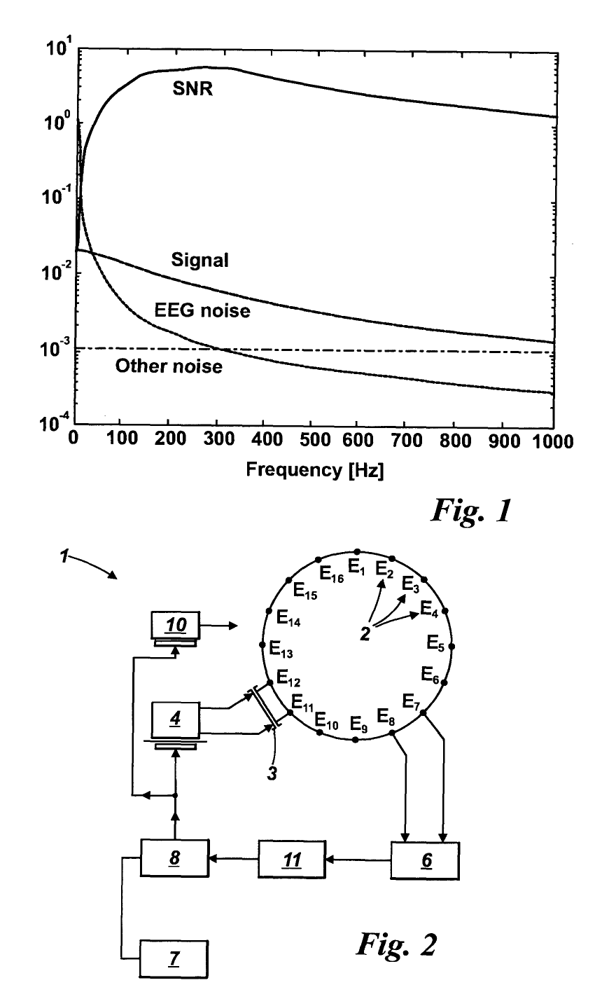

The electroencephalogram noise falls off rapidly over about 70 Hz. Modelling indicated that the impedance change signal also fell off rapidly with recording frequencies greater than 100 Hz, but it has been found that it does not decrease as rapidly as the electroencephalogram noise. FIG. 1 shows a graph which demonstrates this. As can be seen, it has been found that there is a region of frequencies in which a higher signal to noise ratio (labelled “SNR”) should be obtainable, despite a substantial reduction in the magnitude of the impedance change output signal, (labelled “signal”). The magnitude of the noise from electroencephalogram (labelled “EEG”) decreases with increasing frequency while other noise (labelled “other noise”) such as electrical noise has been found to be typically constant over this frequency band.

Thus, importantly, the background electroencephalogram noise decreases more significantly over a particular range of frequencies, thereby increasing the signal to noise ratio. It has been found, rather counter-intuitively, that the signal to noise ratio can be significantly improved using higher input signal frequencies despite the resulting reduction in the already small impedance change of the measured impedance change signal.

According to a first aspect of the present invention we provide an impedance tomography apparatus for the measuring of the electrical activity of excitable tissue, the apparatus comprising a plurality of signal transfer devices adapted for transferring an input signal to a body and receiving an output signal from a body, an input signal generator adapted to generate an electrical input signal and apply it to at least one of the signal transfer devices, a measurement device arranged to measure the output signal from the body at at least one or more of the remaining signal transfer devices, wherein the input signal generator is adapted to substantially generate an input signal of frequency greater than 100 Hz and less than 5 kHz.

The apparatus is advantageous as the signal to noise ratio of the impedance change due to the electrical activity of excitable tissue, such as the depolarisation of nervous or muscle tissue, is sufficiently high for measurements to be extracted. Thus, a meaningful direct measurement of electrical activity can be obtained for use in generating a tomographical image. Accordingly, tomographic images of neuronal depolarization in grey matter, which reflects the sum of activity in a local region, can be created from the measurements. The effective imaging of electrical activity of the brain is particularly advantageous for non-invasive clinical and/or psychiatric applications. The imagery could be useful for the investigation of epilepsy and in epilepsy surgery. It would be especially useful also in studies of normal brain function in the field of cognitive neuroscience. The present invention allows measurement to be made of rapid bulk impedance changes due to depolarization of nervous or muscular tissue and, in particular, for measuring electrical neuronal activity due to neuronal depolarisation in the human brain. The use of these frequencies for the input signal yields useful results.

Preferably, the measurement device is adapted to sample data at a time resolution substantially of the order of milliseconds. In particular, the measurement device is adapted to sample data at a time resolution of less than 1 millisecond. This is advantageous as it is by sampling the output signal at this fine time resolution that fast impedance changes, such as due to depolarisation of nervous or muscle tissue, can be discerned and imaged.

Preferably the apparatus is arranged to measure the neuronal depolarisation in the brain. Alternatively, it may be arranged to measure electrical activity of muscle fibres. Thus, the apparatus may be used to monitor heart activity. Analysis of the depolarisation of neurons in the heart muscle would be a particularly advantageous aid in identifying the sources of fibrillation accurately which is still an open problem in electrocardiography. Further, it could permit imaging of aberrant electrical activation of heart muscle and allow pinpointing of aberrant conduction pathways. For skeletal muscle this could be used to identify muscle inflammation or nerve damage.

Preferably the apparatus includes an imaging device adapted to create an image using the measured electrical output signals.

Preferably, the signal generator is adapted to generate an electrical input signal of sinusoidal form that has a frequency greater than 100 Hz and less that 5 kHz. The use of a signal comprising a sine wave is advantageous as it is the most efficient way to deliver energy at the optimal frequency. It will be appreciated that a wave of a different shape could be employed but would contain energies at other frequencies. As the component frequencies are critically related to the optimal recording frequency, the use of a pure sine wave yields reliable results.

Preferably the apparatus includes a data processing device arranged to receive the measurements made by the measurement device and derive a resistance and reactance change.

Preferably the input signal generator generates an input signal having a frequency of between 100 Hz and 1 kHz and most preferably between 175 Hz and 425 Hz. Preferably, the input signal is of sinusoidal form.

Preferably, the signal transfer devices are electrodes adapted for contact with the skin. Alternatively, the signal transfer devices may comprise magnetic induction input devices for generating an input signal in the body by magnetic means and magnetic detection devices for detecting the output signal. Such magnetic devices are used in magnetic resonance electrical impedance tomography, magneto-encephalography and magnetic induction tomography and comprise coils adapted to be driven to generate a magnetic field. It will be appreciated that any combination of electrical based signal transfer devices and/or magnetic based signal transfer devices may be used.

Preferably the apparatus is adapted to have sufficient sensitivity to resolve signals changes of the order of 0.001%. As discussed above these are the typical levels of the impedance changes measured from the scalp when taking account of the spontaneous electrical activity of the brain.

According to a second aspect of the invention, we provide a method of measuring the electrical activity of excitable tissue using impedance tomography apparatus, the method comprising the steps of;
applying an input signal having a frequency greater than 100 Hz and less that 5 kHz to a body;
measuring the output signal from the body.

This is advantageous as the output signal from the body, when the input signal is between 100 Hz and 5 kHz has been found to have a signal to noise ratio that can provide repeatable and accurate measurements of electrical neuronal activity. In particular, these measurements are sufficiently defined for a tomographical image to be generated.

Preferably, the input signal has a sinusoidal waveform. This is advantageous as the input signal has a single pure frequency and the effect of neuronal activity can be extracted.

Preferably the method includes the step of measuring the output signal with a time resolution substantially of the order of milliseconds. In particular, the method may include the step of measuring the data at a time resolution of less than 1 millisecond. This is advantageous as it is by sampling the output signal at this fine time resolution that fast impedance changes, such as due to depolarisation of nervous or muscle tissue, can be discerned and imaged.

Muscle fibres produce evoked electrical activity with ion channel opening similar to that in the brain or peripheral nerve. Electrical impedance tomography could be used to measure and image the propagation of electrical activity within muscles. This can be used to study how electrical activity spreads in muscle. In the muscle, there are neurons which activate the muscle fibres. A single neuron can activate hundreds of fibres which are then depolarized as the initiating mechanism before they contract. Accordingly, there will be an associated impedance change.

According to a third aspect of the invention, we provide a muscle activity impedance tomography apparatus for measuring the impedance change due to the electrical activity of muscle fibres, comprising a plurality of signal transfer devices adapted for transferring an input signal to a muscle and receiving an output signal from the muscle, an input signal generator adapted to generate an electrical input signal and apply it to at least one of the signal transfer devices, a measurement device arranged to measure the output signal from the muscle at at least one or more of the remaining signal transfer devices.

This is advantageous as measuring the impedance changes that occur as a direct result of the electrical activity of the muscle fibres can provide insights into the functionality and biophysics of muscle operation.

There now follows, by way of example only, a detailed description of the present invention with reference to the accompanying drawings in which;

FIG. 1 shows a graph of the magnitude of a measured change in impedance due to electrical activity of excitable tissue with respect to input signal frequency and the magnitude of noise with respect to input signal frequency;

FIG. 2 shows an embodiment of electrical impedance tomography apparatus; and

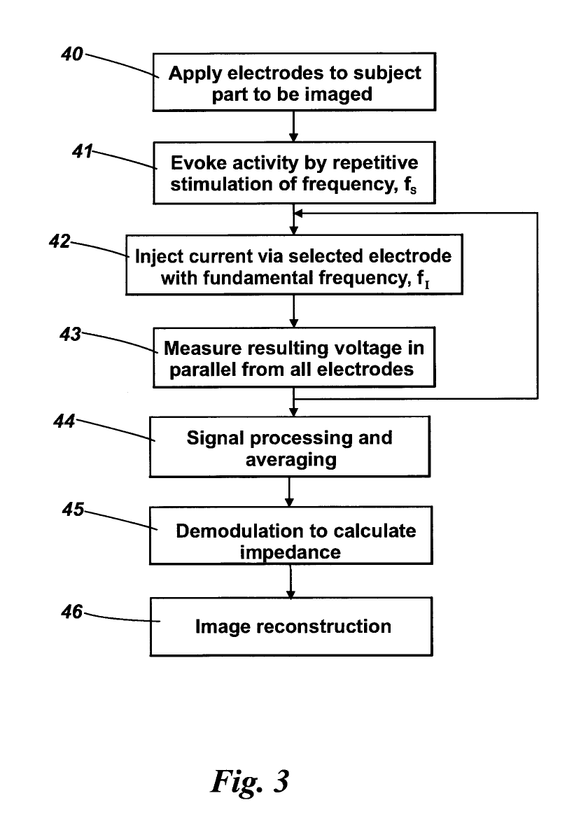

FIG. 3 shows a flow chart representing the operation of the apparatus of FIG. 3.

An embodiment of impedance tomography apparatus 1 for measuring the electrical activity of excitable tissue is shown in FIG. 2, which uses electrical impedance tomography techniques. The apparatus 1 comprises a plurality of signal transfer devices in the form of electrodes 2, labelled individually as E₁ to E₁₆. In this example, sixteen electrodes are used, but more or less may be used depending on the object to be imaged, resolution required and time allowed. The electrodes 2 are equally spaced and provided on a flexible band 2 for selective positioning and attachment on a patient's scalp. Alternatively, the electrodes 2 may be applied to the brain in the form of a grid of platinum electrodes on a silicone rubber backing, each approximately 0.6 mm in diameter and spaced with centres 1 mm apart, for example.

Each of the electrodes 2 are connected to a switching device 3 such as a computer controlled multiplexer. The switching device 3 is controllable so that an input electrical signal can be applied to various combinations of electrodes in turn.

An input signal current generator 4 is adapted to generate an input current and apply it to the electrodes 2 selected by the switching device 3. An output signal, in this case potential difference, is measured and received by an amplifier 6. In FIG. 2, the input current is presently applied to the scalp by electrodes E₁₁ and E₁₂ and the output signal is received by electrodes E₇ and E₈. The switching device 3 can change the electrodes 2 that apply the input signal and further measurements can be made.

The apparatus 1 is controlled by a control device 7, which may be a computer. The control device 7 communicates with the input signal current generator 4 via an interface 8. The control device 7 is also adapted to control a stimulus pulse generator 10. The stimulus pulse generator 10 is arranged to provide the patient with a stimulus, for example a visual stimulus in the form of a flashing light.

The input signal current, having passed through the patient's head, is detected by the electrodes 2. The amplifier 6 is arranged to amplify the signal and an analogue to digital convertor 11 is arranged to receive the amplified signal, digitize it and pass it to the control device 7 via the interface 8. The analogue to digital convertor 11 may be a 16-bit analogue to digital convertor. A data processing device, arranged to process the measurements of the output signal, is embodied as software on the control device 7. The measurement device is embodied as parts 6, 11, 8 and 7. The measurement device is adapted to sample data at a time resolution substantially of the order of 1 millisecond (although it may be adapted to sample at a time resolution of less than 100 milliseconds, less than 10 milliseconds or less than 1 millisecond, as required). Thus, the components are chosen to reliably perform at the chosen resolution.

The general concept of data acquisition by applying an electrical input signal and measuring the impedance with such apparatus is known and will not be described in detail here. However, in summary, the control device 7 causes the input signal generator 4 to apply the alternating constant current to a first set of electrodes. The stimulus pulse generator 10 is also activated to provide, in this embodiment, a visual stimulus to the patient. The control device 7 records the measurements of the output electrical signal. The switching means 3 changes the electrodes that apply the input signal and further measurements are made.

The current generator 4 of the present embodiment is adapted to generate a sinusoidal waveform substantially at a frequency of 225 Hz. This choice of frequency is advantageous as it is midway between mains frequency harmonics (e.g. for mains frequency of 50 Hz, the midway points are 125, 175, 225, 275 Hz etc). This way, the subtraction of measurements made at opposed polarities will also reject any 50 Hz noise and all its harmonics as disclosed in U.S. Pat. No. 5,919,142. This is a known technique and will therefore not be discussed in detail.

It will be appreciated that in countries using 60 Hz for mains power, the choice of stimulus and sine wave frequencies needs to be selected differently to satisfy both rejection of mains harmonics and inverting the sine wave phase between consecutive stimuli.

Further, at a frequency of approximately 225 Hz, preliminary results show that the impedance change signal was about 0.001% for measured neuronal activity and wherein the signal-to-noise ratio may be about 5. The change when measured directly on exposed cerebral cortex was 0.05%. It has been found that frequencies in the range 100 Hz to 5 kHz are appropriate for neuronal activity imaging in the brain in human or other species or other electrical activity in excitable tissue. In particular, a frequency range of 100 Hz to 1 kHz has been found to yield accurate results. Ranges from any of 150, 200, 250, 300, 350, 400 and 450 Hz to any of 500, 550, 600, 650, 700, 750, 800, 850, 900, 950 Hz or 1 kHz, 1.5 kHz, 2 kHz, 2.5 kHz, 3 kHz, 3.5 kHz, 4 kHz, 4.5 kHz have also been found to be advantageous.

FIG. 3 comprises a flow chart showing the operation of an embodiment of the apparatus 1.

At step 40, the electrodes E₁ to E₁₆ are applied to the subject to be imaged. In the case of non-invasive brain imaging, multiple electrodes are applied to the scalp of the subject's head. It is also possible to use intracranial electrodes in some circumstances to achieve further improved imaging resolution.

At step 41, the stimulus pulse generator 10 provides a somatosensory, auditory or visual stimulus that is applied to the subject to evoke a response in the neurones of the brain. The frequency fₛ of the applied stimulus is selected according to an appropriate recovery/response time of the somatosensory, auditory or visual system. In this embodiment a visual stimulus in the form of a flashing light is used at a frequency of approximately 2 Hz. The frequency fₛ is also chosen to be an odd multiple of the half period of the injection current frequency. In this way, the stimulus is applied in alternate phases of the injected current carrier to allow the use of the prior art “subtraction method” as disclosed in U.S. Pat. No. 5,919,142. Thus, an fₛ of 2 Hz can be used in combination with an input signal frequency comprising an odd sine wave at 125 Hz. This way, we have 62.5 sine wave cycles during each half second stimulus period, S. The stimulus is then applied continuously over the measurement period, T. This period, T, is selected to allow effective averaging of measurements to improve the signal to noise ratio. In this embodiment T is 1 minute.

The duration of T is a trade-off between obtaining accurate measurements through averaging with longer T times and obtaining images that accurately represent physiological reactions to a stimulus using low T times. It is known that as the noise is uncorrelated, it will reduce by the square root of the number of averages made. On the other hand, it would be desirable to minimise the total recording time in order to obtain accurate images, as physiological conditions in the subject may alter over a protracted recording period, and many different electrode combinations are required to produce a data set for recording. T is therefore generally empirically set at the minimum time required to produce a signal to noise ratio of about 4 to 5. This is typically of the order of 1 minute for current injection at one set of electrodes.

At step 42, the input current signal is injected through a pair of electrodes 2 selected by switching means 4, using a fixed amplitude carrier with a fundamental frequency between 100 and 5000 Hz. The optimal frequency depends on the precise neuronal activity measurements being made and is a compromise between the decrease in the measured signal impedance change and noise as frequency increases. In current studies in an anaesthetised rat with subdural electrodes, the ideal frequency has been found empirically to be 255 Hz. It will be appreciated by those skilled in the art that this may vary for studies in humans or other species and with different electrode positions and types—e.g. subdural, intracerebral or scalp electrodes and also using different anaesthesia states and agents. In the present embodiment, a sinusoidal wave of 225 Hz is used.

At step 43, the resulting voltage is recorded from multiple electrodes 2 simultaneously for any one input signal using a multi-channel acquisition system. Multiple measurements are made at a resolution of 1 ms (although a time resolution of less than 1 ms may be used) throughout the measurement period, T, for many repetitions of the stimuli in order to allow averaging for a specific current injection pair. Neuronal activity (and the resulting impedance changes) is changing very rapidly and therefore the goal is to describe it (with a 3D image tomographic image) at each time point of about 1 ms. The measurements made represent the electrical activity of neurons due to the stimulus. Thus, the measurements show a “visually evoked potential” of the neurons in response to application of the stimulus. The frequency of the input signal within the defined range allows the effective measurement of the impedance change directly caused by the electrical activity of excitable tissue. Thus, the depolarisation of neuronal cells in the brain or the electrical activity of muscle fibres can be measured effectively.

Steps 42 to 43 are then repeated N times for different selected current injection electrode pairs 2.

At step 44, signal processing and averaging techniques are applied to improve the signal to noise ratio of the measurement dataset. Appropriate techniques will be known to those skilled in the art and will therefore not be discussed in detail. The signal processing and averaging leave a dataset with improved signal to noise ratio, which represents the averaged measured potential waveform for the duration of two consecutive stimulus periods i.e. 2 S (one second for 2 Hz stimuli). These measurements reveal changes during the times of synchronous depolarization.

At step 45, the measurement dataset is demodulated to calculate the impedance change caused by the neuronal activity. The averaged waveform for the two consecutive stimulus periods, S are added or subtracted in order to demodulate the transient change in potential, 8 due to the decrease in impedance as a result of stimulated neuronal activity, which is a known technique in the art as discussed above. In the current method, demodulation of the complex impedance changes takes account of both impedance components: impedance |Z| and phase φ (or the equivalent resistance R and reactance X).

The outcome of this method is a set of impedance modulus and phase (or resistance and reactance) waveforms for each of the current injection pairs. The measurements obtained using the disclosed technique have been found to be surprisingly productive at enabling the extraction of the very small impedance changes amongst the high background noise.

At step 46, these measurements can then be used by an imaging device, embodied as software in the control device 7, to generate a tomographic image. The values of relative impedance and phase are inserted into an electrical impedance tomography solver for reconstruction of a time movie of tomographic slices in accordance with image construction techniques that will be known to those skilled in the art.

The current embodiment is described in the context of Electrical Impedance Tomography where fixed currents are injected and voltages measured. However, it is also possible to apply a fixed voltage and measure the resulting current. The signal transfer devices may be magnetic based or electrically based. Thus, it will be appreciated by the skilled man that the method applies to magnetic techniques such as Magnetic Resonance (MR-EIT), Magnetic Induction Tomography and Magneto-Encephalography (MEG) where electrodes are replaced by small, inductive coils arranged on the inside of a helmet close to the subject's scalp. Currents may be induced by such coils. It will further be appreciated that various combinations of the electrical and magnetic signal transfer devices mentioned can be used. When using MR-EIT, a small number of electrodes are used to inject current and an MRI machine is used to map the changes in magnetic fields. This is anticipated to provide a spatial resolution of between ˜0.1-1 mm.

Further, neural activity may be detected using sensing coils and Superconducting QUantum Interference Devices (SQUID). The magnetic field is not attenuated by the skull as the electric potentials, so MEG is theoretically more sensitive. The problem of contact impedance is avoided, since the sensors do not come into contact with the scalp, and the positions of the electrodes are well defined. However, magnetic apparatus is expensive and immobile. It requires a dedicated, shielded room and also high maintenance costs.

The apparatus of FIG. 2 may be used to measure the electrical activity of muscle. The electrodes 2 will be applied to the muscle to be measured rather that the patient's scalp. Further, it has been found that the input signal current generator 4 may be arranged to generate an input current of sinusoidal waveform. Alternatively, in this embodiment, it may be arranged to generate a first input signal over a first time period and a second input signal over a second time period. The first input signal may be an inverted form of the second input signal and thus the generator 11 may produce a substantially square waveform. The data acquisition and operation of the apparatus is as discussed above.

1. An impedance tomography apparatus for the measuring of the electrical activity of excitable tissue, the apparatus comprising:
a plurality of signal transfer devices adapted for transferring an input signal to a body and receiving an output signal from a body;
an input signal generator adapted to generate an electrical input signal and apply it to at least one of the signal transfer devices; and
a measurement device arranged to measure the output signal from the body at at least one or more of the remaining signal transfer devices, wherein the input signal generator is adapted to generate an input signal of frequency greater than 100 Hz and less that 5 kHz and the measurement device is adapted to sample data at a time resolution substantially of the order of milliseconds or less than one millisecond.

2. An impedance tomography apparatus according to claim 1, wherein the apparatus is arranged to measure the neuronal depolarisation in the brain.

3. An impedance tomography apparatus according to claim 1, wherein the apparatus is arranged to measure electrical activity of muscle fibres.

4. An impedance tomography apparatus according to claim 1, wherein the signal generator is adapted to generate an electrical input signal of sinusoidal form that has a frequency greater than 100 Hz and less that 5 kHz.

5. An impedance tomography apparatus according to claim 1, wherein the apparatus includes a data processing device arranged to receive the measurements made by the measurement device and derive a resistance and reactance change.

6. An impedance tomography apparatus according to claim 1, wherein the input signal generator generates an input signal having a frequency of between 100 Hz and 1 kHz

7. An impedance tomography apparatus according to claim 1, wherein the input signal generator generates an input signal having a frequency between 175 Hz and 425 Hz.

8. An impedance tomography apparatus according to claim 1, wherein the signal transfer devices are electrodes adapted for contact with the skin.

9. An impedance tomography apparatus according to claim 1, wherein the signal transfer devices comprise magnetic induction input devices for generating an input signal in the body by magnetic means and magnetic detection devices for detecting the output signal.

10. An impedance tomography apparatus according to claim 1, wherein the signal transfer devices arranged to provide the input signal comprise electrodes and wherein the signal transfer devices arranged to detect the output signal comprise magnetic sensing coils.

11. (canceled)

12. An impedance tomography apparatus according to claim 1, wherein the measurement device is adapted to sample data at a time resolution of less than 1 millisecond.

13. A method of measuring the electrical activity of excitable tissue using impedance tomography apparatus, the method comprising:
applying an input signal having a frequency greater than 100 Hz and less that 5 kHz to a body; and
measuring the output signal from the body with a time resolution substantially of the order of milliseconds.

14. A method according to claim 13, wherein the input signal has a sinusoidal waveform.

15. (canceled)

16. A method according to claim 13, further comprising:
measuring the data at a time resolution of less than 1 millisecond.

17. A muscle activity impedance tomography apparatus for measuring the impedance change due to the electrical activity of muscle fibres, comprising:
a plurality of signal transfer devices adapted for transferring an input signal to a muscle and receiving an output signal from the muscle;
an input signal generator adapted to generate an electrical input signal and apply it to at least one of the signal transfer devices; and
a measurement device arranged to measure the output signal from the muscle at at least one or more of the remaining signal transfer devices.
